(19) United States
(12) Patent Application Publication
(10) Pub. No.: US 2025/0031394 A1
(43) Pub. Date: Jan. 23, 2025

(54) SEMICONDUCTOR DEVICE

(71) Applicant: FUJI ELECTRIC CO., LTD., Kawasaki-shi (JP)

(72) Inventors: Shin MIYAMOTO, Matsumoto-city (JP); Yuichi HASHIZUME, Matsumoto-city (JP)

(73) Assignee: FUJI ELECTRIC CO., LTD., Kawasaki-shi, Kanagawa (JP)

(21) Appl. No.: 18/678,810

(22) Filed: May 30, 2024

(30) Foreign Application Priority Data
Jul. 21, 2023 (JP) 2023-119445

(51) Int. Cl. H01L 29/872; H01L 21/04; H01L 29/06; H01L 29/16; H01L 29/66

(52) U.S. Cl. CPC H01L 29/872; H01L 21/0465; H01L 21/0475; H01L 29/0657; H01L 29/1608; H01L 29/6606

(57) ABSTRACT

A semiconductor device, including: a semiconductor substrate including a first-conductivity-type region at a first main surface; a second-conductivity-type region selectively provided at the first main surface and extending in a first direction parallel to the first main surface; a first electrode provided at the first main surface, forming a Schottky junction with the first-conductivity-type region and being in contact with the second-conductivity-type region; and a second electrode provided on a second main surface. The first-conductivity-type region and the second-conductivity-type region includes a plurality of upper surface portions that are aligned in both the first direction and a second direction parallel to the first main surface and perpendicular to the first direction. Each of the upper surface portions forms a first step with another upper surface portion adjacent thereto in the second direction, and forms a second or third step with another upper surface portion adjacent thereto in the first direction.

### CROSS REFERENCE TO RELATED APPLICATIONS

This application is based upon and claims the benefit of priority of the prior Japanese Patent Application No. 2023-119445, filed on Jul. 21, 2023, the entire contents of which are incorporated herein by reference.

### BACKGROUND OF THE INVENTION

### 1. Field of the Invention

Embodiments of the invention relate to a semiconductor device.

### 2. Description of the Related Art

In a Schottky barrier diode (SBD) used as a power device, one known device adopts a junction barrier Schottky (JBS) structure at a front side of a semiconductor substrate; the JBS has both a Schottky junction and a pn junction; and a p⁺-type region forming the pn junction is formed in a region at a surface of an inner wall of an anode trench (for example, refer to Japanese Laid-Open Patent Publication No. 2014-116471, Japanese Laid-Open Patent Publication No. 2018-101668, and Japanese Laid-Open Patent Publication No. 2011-009797).

### SUMMARY OF THE INVENTION

According to one aspect of the present invention, a semiconductor device includes: a semiconductor substrate of a first conductivity type, having a first main surface and a second main surface opposite to each other, the semiconductor substrate having a first-conductivity-type region at the first main surface thereof; a second-conductivity-type region of a second conductivity type, selectively provided at the first main surface of the semiconductor substrate, both the second-conductivity-type region, and the first-conductivity-type region extending along the second-conductivity-type region, extend at the first main surface in a first direction parallel to the first main surface; a first electrode provided at the first main surface of the semiconductor substrate, the first electrode forming a Schottky junction with the first-conductivity-type region and being in contact with the second-conductivity-type region at the first main surface; and a second electrode provided at the second main surface of the semiconductor substrate, wherein an upper surface of the first-conductivity-type region includes a plurality of first-conductivity-type upper surface portions, and an upper surface of the second-conductivity-type region includes a plurality of second-conductivity-type upper surface portions, the plurality of first-conductivity-type upper surface portions and the plurality of second-conductivity-type upper surface portions being aligned in both the first direction and a second direction, which is parallel to the first main surface and perpendicular to the first direction; in the second direction, each of the first-conductivity-type upper surface portions has a first difference in height, in a depth direction of the semiconductor device, with one of the second-conductivity-type upper surface portions adjacent thereto, to thereby form a first step therebetween; in the first direction, each of the first-conductivity-type upper surface portions has a second difference in height, in the depth direction of the semiconductor device, with one of the first-conductivity-type upper surface portions adjacent thereto, to thereby form a second step therebetween; and in the first direction, each of the second-conductivity-type upper surface portions has a third difference in height, in the depth direction of the semiconductor device, with one of the second-conductivity-type upper surface portions adjacent thereto, to thereby form a third step therebetween.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a perspective view depicting a structure of a semiconductor device according to a first embodiment.

FIG. 2 is a cross-sectional view of the structure along cutting line A-A′ in FIG. 1.

FIG. 3 is a cross-sectional view of the structure along cutting line B-B′ in FIG. 1.

FIG. 4 is a cross-sectional view of the structure along cutting line C-C′ in FIG. 1.

FIG. 5 is a cross-sectional view of the structure along cutting line D-D′ in FIG. 1.

FIG. 6 is a cross-sectional view depicting another example of the structure along cutting line D-D′ in FIG. 1.

FIG. 7 is a plan view depicting another example of a layout when the semiconductor device according to the first embodiment is viewed from a front side of the semiconductor substrate.

FIG. 8 is a cross-sectional view depicting a state of the semiconductor device according to the first embodiment during manufacture.

FIG. 9 is a cross-sectional view depicting a state of the semiconductor device according to the first embodiment during manufacture.

FIG. 10 is a cross-sectional view depicting a state of the semiconductor device according to the first embodiment during manufacture.

FIG. 11 is a cross-sectional view depicting a state of the semiconductor device according to the first embodiment during manufacture.

FIG. 12 is a cross-sectional view depicting a state of the semiconductor device according to the first embodiment during manufacture.

FIG. 13 is a cross-sectional view depicting a state of the semiconductor device according to the first embodiment during manufacture.

FIG. 14 is a cross-sectional view depicting a state of the semiconductor device according to the first embodiment during manufacture.

FIG. 15 is a cross-sectional view depicting a state of the semiconductor device according to the first embodiment during manufacture.

FIG. 16 is a cross-sectional view depicting a structure of a semiconductor device according to a second embodiment.

FIG. 17 is a cross-sectional view depicting a structure of a semiconductor device according to a second embodiment.

FIG. 18 is a cross-sectional view depicting a structure of a semiconductor device according to a second embodiment.

FIG. 19 is a cross-sectional view depicting a structure of a semiconductor device according to a second embodiment.

FIG. 20 is a cross-sectional view depicting a state of the semiconductor device according to the second embodiment during manufacture.

FIG. 21 is a cross-sectional view depicting a state of the semiconductor device according to the second embodiment during manufacture.

FIG. 22 is a perspective view depicting a structure of a semiconductor device of a reference example.

FIG. 23 is a cross-sectional view depicting the structure along a cutting line AA-AA′ in FIG. 22.

### DETAILED DESCRIPTION OF THE INVENTION

First, problems associated with the conventional techniques are discussed. Conduction loss of an SBD is lower the greater is an area of contact between an n-type semiconductor substrate and a Schottky electrode (area of the Schottky junction). However, in the SBD of the JBS structure, both a Schottky junction and a pn junction are present at the front side of the semiconductor substrate and the area of the Schottky junction is reduced by the area of a pn junction diode formed by the pn junction and thus, conduction loss is greater as compared to the conduction loss of an SBD of the same chip size and having only a Schottky junction.

Embodiments of a semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

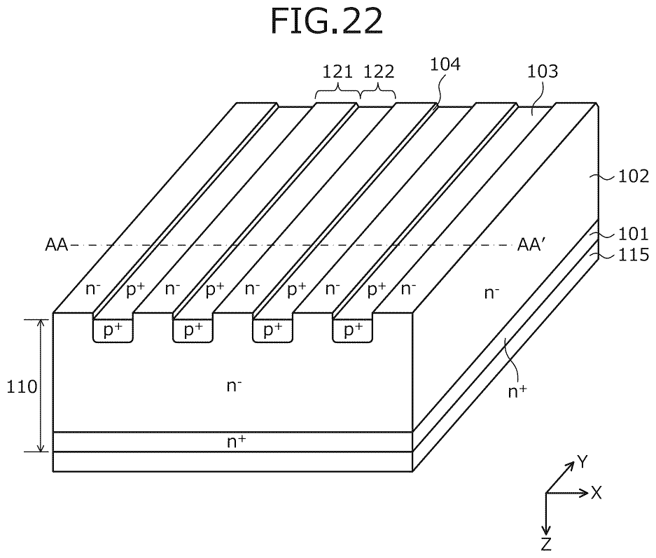

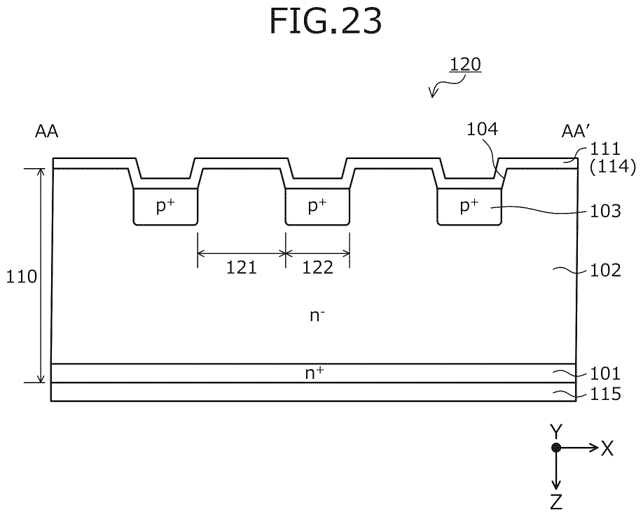

As a result of intensive research, the present inventor found the following. A structure of a semiconductor device of a reference example is described. FIG. 22 is a perspective view depicting a structure of the semiconductor device of the reference example. In FIG. 22, to clearly depict a layout of a JBS structure and trenches 104, an anode electrode 114 is not depicted. FIG. 23 is a cross-sectional view depicting the structure along a cutting line AA-AA′ in FIG. 22. A semiconductor device 120 of the reference example depicted in FIGS. 22 and 23 is a SiC-SBD of a JBS structure having both Schottky junctions and pn junctions at a front side of a semiconductor substrate (semiconductor chip) 110 containing silicon carbide (SiC), the semiconductor device 120 having Schottky junction regions 121 and pn junction regions 122 repeatedly alternating with one another in a first direction X parallel to a front surface of the semiconductor substrate 110.

In the Schottky junction regions 121, SBDs are formed by Schottky junctions between an n-type drift region 102 and a Schottky electrode 111 directly beneath the anode electrode 114. In the pn junction regions 122, pn junction diodes are formed by pn junctions between p⁺-type regions 103 and the n-type drift region 102. The SBDs of the Schottky junction regions 121 and the pn junction diodes of the pn junction regions 122 are connected in parallel by the Schottky electrode 111 and a cathode electrode 115. The Schottky junction regions 121 and the pn junction regions 122 each extend in a stripe-shape in a second direction Y parallel to the front surface of the semiconductor substrate 110 and orthogonal to the first direction X.

The p⁺-type regions 103 are provided between the n-type drift region 102 and the trenches 104. The p⁺-type regions 103 are provided apart from one another in the first direction X and each extends in a stripe-shape in the second direction Y. Between any adjacent two of the p⁺-type regions 103, a portion of the n-type drift region 102 extends to the front surface of the semiconductor substrate 110. Regions where the p⁺-type regions 103 are provided constitute the pn junction regions 122 while regions between the p⁺-type regions 103, which are adjacent to one another, constitute the Schottky junction regions 121. The trenches 104 are formed as a secondary consequence of over-etching performed to assuredly form openings in an ion implantation mask used to form the p⁺-type regions 103; the trenches 104 are formed in the semiconductor substrate 110, at the front surface thereof, in a same pattern as a pattern of the openings in the ion implantation mask.

Impurities in SiC have a small diffusion coefficient and diffuse minimally. The p⁺-type regions 103 are formed by ion-implanting a p-type impurity at bottoms of the trenches 104 via the ion implantation mask, each of the p⁺-type regions 103 has a width substantially the same as a width of the bottom of any one of the trenches 104 and only underlies the bottom of the trench 104. The Schottky electrode 111 is provided along inner walls of the trenches 104 and the front surface of the semiconductor substrate 110 in an active region. The Schottky electrode 111 is in contact with the n-type drift region 102 at the front surface of the semiconductor substrate 110 and sidewalls of the trenches 104 and is in contact with the p⁺-type regions 103 at the bottoms of the trenches 104. At a back side of the semiconductor substrate 110, an n⁺-type cathode region 101 and the cathode electrode 115 are provided.

In general, conduction loss of an SBD is smaller the greater is the area of contact between an n⁻-type semiconductor substrate and the Schottky electrode (area of the Schottky junction). One reason is, similar to the resistance of wiring being lower the greater is the diameter of the wiring (cross-sectional area), the greater is the area of the Schottky junction, the greater is the cross-sectional area of the path of forward current of the SBD and thus, internal resistance of the SBD decreases. In the described semiconductor device 120 of the reference example (SiC-SBD of the JBS structure), across the front surface of the semiconductor substrate 110 and the sidewalls of the trenches 104, the n⁻-type drift region 102 and the Schottky electrode 111 form a Schottky junction and thus, due to the trenches 104, the area of the Schottky junction increases and conduction loss decreases.

On the other hand, impurities in silicon (Si) have a large diffusion coefficient and easily diffuse. When the described semiconductor device 120 of the reference example is applied to a Si-SBD (not depicted) of a JBS structure containing Si as a semiconductor material, the p-type impurity ion-implanted at the bottom of a trench formed by the over-etching during the formation of the ion implantation mask diffuses radially, whereby the p⁺-type region forming a pn junction of the JBS structure is formed along the entire surface of the inner wall of the trench. Due to the trench, the area of contact between the Schottky electrode and the p⁺-type region forming the pn junction of the JBS structure increases. As a result, an allowable amount of current of the pn junction diode increases and an amount of tolerance against large currents (surge currents, inrush currents, etc.) exceeding a rated current is enhanced. Further, the area of the pn junction increases and thus, an effect of suppressing leakage current during reverse bias increases.

However, the trenches 104 each have the same width as the width of each of the p⁺-type regions 103 due to the over-etching during the formation of the ion implantation mask for forming the p⁺-type regions 103. As a result, the number of the trenches 104 that may be formed in the active region is limited by the pattern of the p⁺-type regions 103 and the effect of increasing the area of contact with the Schottky electrode 111 by the trenches 104 is limited. Further, the trenches 104 are not intentionally formed aiming at a predetermined effect and thus, a contribution rate to the improvement of electrical characteristics of the SBD of the JBS structure (for example, reduction of conduction loss, improvement of fracture resistance, etc.) is low. Therefore, one issue to be resolved in the present embodiment is improvement of electrical characteristics of the SBD of s JBS structure.

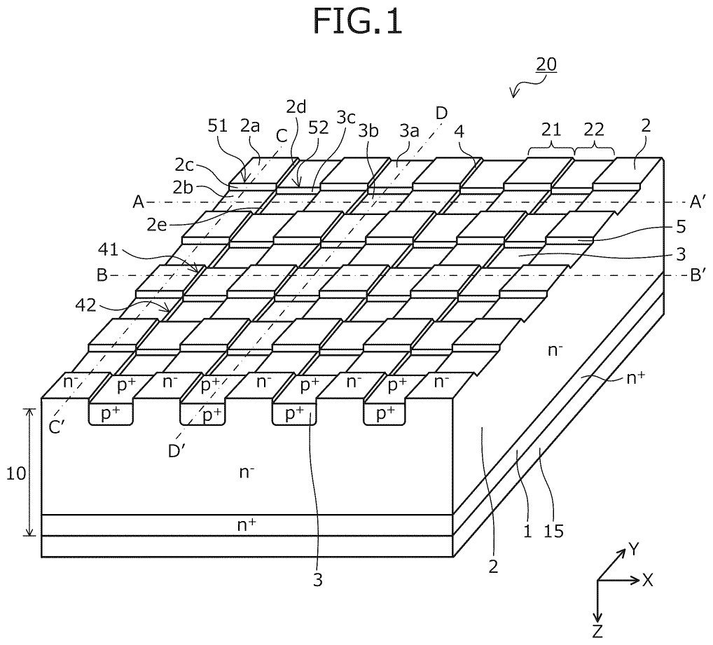

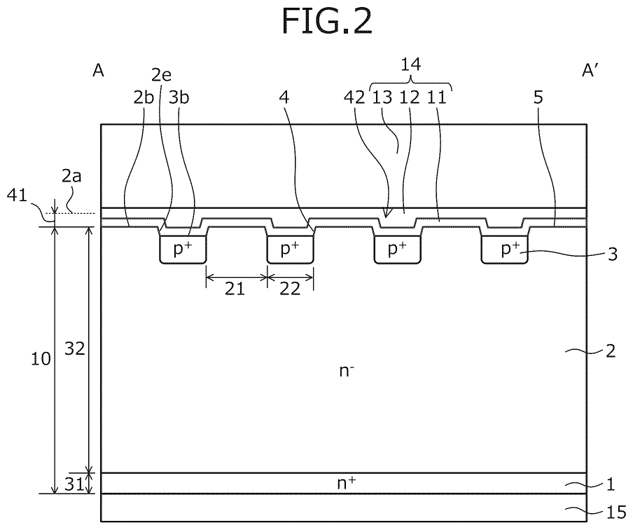

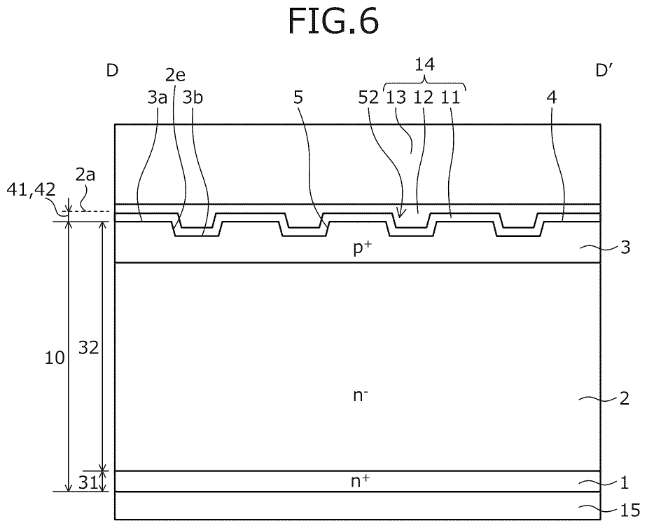

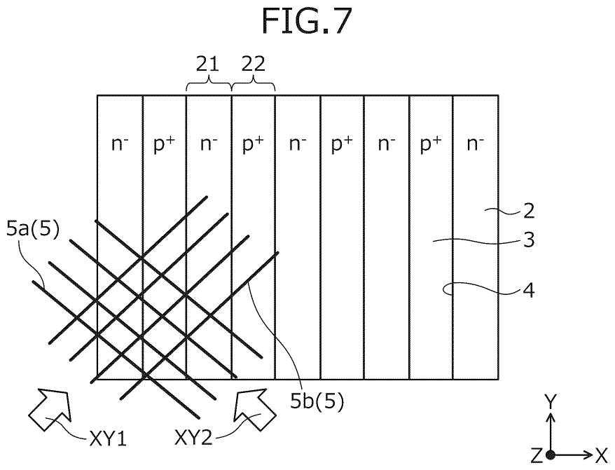

A structure of a semiconductor device according to a first embodiment is described. FIG. 1 is a perspective view depicting the structure of the semiconductor device according to the first embodiment. In FIG. 1, an anode electrode 14 is not depicted. FIGS. 2, 3, 4, and 5 are cross-sectional views of the structure along cutting line A-A′, cutting line B-B′, cutting line C-C′, and cutting line D-D′ in FIG. 1, respectively. FIG. 6 is a cross-sectional view depicting another example of the structure along cutting line D-D′ in FIG. 1. In FIGS. 2, 5, and 6, a height of first n-type surface portions 2a of a front surface of a semiconductor substrate 10 is indicated by a dashed line. FIG. 7 is a plan view depicting another example of a layout when the semiconductor device according to the first embodiment is viewed from a front side of the semiconductor substrate. FIG. 7 depicts another example of a layout of second trenches 5 (5a, 5b).

The semiconductor device 20 according to the first embodiment depicted in FIGS. 1 to 5 is a SiC-SBD of a JBS structure in which both Schottky junctions and pn junctions are present at a front side of the semiconductor substrate (semiconductor chip) 10 containing SiC, and the semiconductor device 20 has Schottky junction regions 21 and pn junction regions 22 in an active region. The Schottky junction regions 21 and the pn junction regions 22 are disposed adjacently to one another, repeatedly alternating with one another in the first direction X parallel to the front surface of the semiconductor substrate 10; the Schottky junction regions 21 and the pn junction regions 22 each extend in a stripe-shape in the second direction Y parallel to the front surface of the semiconductor substrate 10 and orthogonal to the first direction X. A pair of any one the Schottky junction regions 21 and an adjacent one of the pn junction regions 22 may extend linearly in the second direction Y. The active region is a region through which forward current flows during conduction of the SBD.

An interlayer insulating film covers an entire area of the front surface of the semiconductor substrate 10 in an edge termination region (not depicted) and has an opening that exposes an entire area of the active region. The edge termination region is a region between the active region and a side surface of the semiconductor substrate 10 and surrounds a periphery of the active region in a plan view of the semiconductor device. The edge termination region has a function of mitigating electric field of the front side of the semiconductor substrate 10 and sustaining a breakdown voltage. The breakdown voltage is a maximum voltage at which no malfunction or destruction of the device occurs. In the edge termination region, a predetermined voltage withstanding structure such as a field limiting ring (FLR) or junction termination extension (JTE) structure is disposed.

In the Schottky junction regions 21, SBDs that use rectification of a Schottky barrier formed at Schottky junctions between a surface of an n-type drift region (first-conductivity-type region) 2 and a surface of a Schottky electrode (first metal layer) 11 are formed. In the pn junction regions 22, pn junction diodes are formed by pn junctions between p⁺-type regions (second-conductivity-type regions) 3 and the n⁻-type drift region 2. The SBDs of the Schottky junction regions 21 and the pn junction diodes of the pn junction regions 22 are connected in parallel by the anode electrode (first electrode) 14 and a cathode electrode (second electrode) 15.

A rated current during forward bias causes the SBDs of the Schottky junction regions 21 conduct. The pn junction diodes of the pn junction regions 22 conduct when a large current (surge currents, inrush currents) exceeding the rated current flows during a load short-circuit or when a power source is turned on/off and thus, have a function of suppressing increases in forward voltage. A value of contact resistance between the Schottky electrode 11 and the p⁺-type regions 3 is determined by the timing when forward current flows into the pn junction diodes of the pn junction regions 22. Further, leakage current is suppressed by a depletion layer that spreads from the pn junctions between the p⁺-type regions 3 and the n-type drift region 2 during reverse bias.

The semiconductor substrate 10 is formed by stacking an n-type epitaxial layer 32 constituting the n⁻-type drift region 2, on a front surface of an n⁺-type starting substrate 31 containing SiC. The semiconductor substrate 10 has, as the front surface, a first main surface having the n⁻-type epitaxial layer 32 and, as a back surface, a second main surface (back surface of the n⁺-type starting substrate 31). The n⁺-type starting substrate 31 constitutes an n⁺-type cathode region 1. In the n⁻-type epitaxial layer 32, a portion thereof excluding the p⁺-type regions 3 constitutes the n⁻-type drift region 2. The p⁺-type regions 3 are provided between bottoms of first trenches and the n⁻-type drift region 2, each of the p⁺-type regions 3 is in contact with the n-type drift region 2 and underlies the bottom of a corresponding one of the first trenches. The p⁺-type regions 3 are provided apart from one another in the first direction X and each extends in a stripe-shaped in the second direction Y.

A width (width in the first direction X) of each of the p⁺-type regions 3 is, for example, in a range of about 2.3 μm to 3 μm. A pitch (arrangement interval in the first direction X (interval between the stripe-shapes)) of the p⁺-type regions 3 is, for example, in a range of about 2.3 μm to 3 μm. The p⁺-type regions 3 are adjacent to one another and portions of the n⁻-type drift region 2 intervening therebetween reach the front surface of the semiconductor substrate 10 to be exposed at the front surface of the semiconductor substrate 10. In the n-type drift region 2, portions thereof exposed at the front surface of the semiconductor substrate 10 are disposed alternating with the p⁺-type regions 3 repeatedly in the first direction X; said portions and the p⁺-type regions 3 each extend in the striped-shape in the second direction Y. Being exposed at the front surface of the semiconductor substrate 10 means being exposed at the front surface of the semiconductor substrate 10 or at inner walls (sidewalls and bottoms) of the later-described first and second trenches 4, 5 and thereby, being in contact with the later-described Schottky electrode 11; portions where the p⁺-type regions 3 are provided constitute the pn junction regions 22. Portions intervening between the adjacent p⁺-type regions 3 constitute the Schottky junction regions 21.

At the front surface of the semiconductor substrate 10, in the active region, the first and second trenches 4, 5 are provided intersecting with one another. Due to the first and second trenches 4, 5, at the front surface of the semiconductor substrate 10, three or more steps (in FIG. 1, steps 41, 42, 51, 52) of different heights are disposed repeatedly in a predetermined pattern. The bottoms of the first and second trenches 4, 5 are positioned at a depth closer to the front surface of the semiconductor substrate 10 than is a lower surface (surface facing the n⁺-type cathode region 1) of a portion of each of the p⁺-type regions 3, the lower surface facing in a depth direction Z. The first and second trenches 4, 5 may each have a substantially rectangular shape or a trapezoidal shape having a width in the first direction X, the width becoming smaller with increasing proximity to the trench bottom. The area of the surface of the n-type drift region 2 exposed at the front side of the semiconductor substrate 10 increases due to the first and second trenches 4, 5 and thus, area of contact (area of the Schottky junction) between the n-type drift region 2 and the Schottky electrode 11 increases.

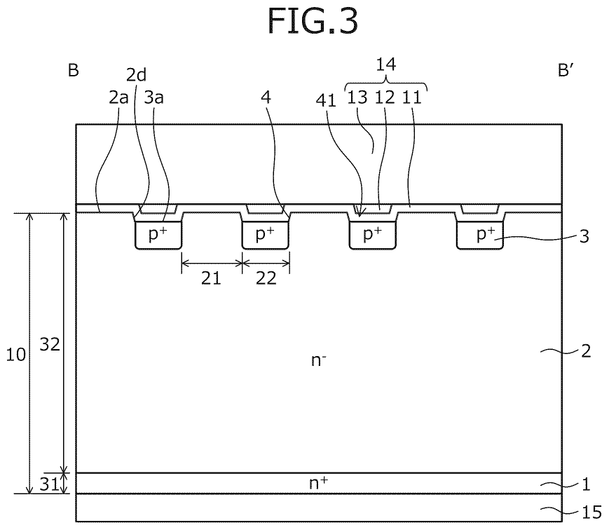

In particular, the first trenches 4 are formed by over-etching during formation of an ion implantation mask used to form the p⁺-type regions 3 and the first trenches 4 are formed in a same pattern as the pattern of the mask openings. Thus, each of the first trenches 4 has substantially a same width (width of the bottom) as the width of each of the p⁺-type regions 3 and the first trenches 4 are formed in the same pattern as the pattern of the p⁺-type regions 3 and at the same positions as the p⁺-type regions 3. Each of the p⁺-type regions 3 is exposed at the entire surface of the bottom of a corresponding one the trenches 4 while the n-type drift region 2 is exposed at the entire surface of each of the sidewalls of the first trenches 4. Due to the first trenches 4, at the front surface of the semiconductor substrate 10, between any one portion of the n-type drift region 2 and an adjacent one of the p⁺-type regions 3, steps (first steps) 41, 42 where upper surface portions (hereinafter, first and second p-type surface portions) 3a, 3b of the p⁺-type region 3 are closer to the n⁺-type cathode region 1 than are upper surface portions (hereinafter, first and second n-type surface portions) 2a, 2b of the n-type drift region 2 are formed (FIGS. 3 and 2).

The first n-type surface portions 2a and the first p-type surface portions 3a are arranged repeatedly alternating with one another in a longitudinal direction of the second trenches 5 with the steps 41 intervening therebetween. At fourth n-type surface portions 2d (sidewalls of the first trenches 4) connecting the first n-type surface portions 2a and the first p-type surface portions 3a, the n-type drift region 2 is exposed. The second n-type surface portions 2b and the second p-type surface portions 3b are arranged repeatedly alternating with one another in the longitudinal direction of the second trenches 5 with the steps 42 intervening therebetween. At fifth n-type surface portions 2e (sidewalls of the first trenches 4) connecting the second n-type surface portions 2b and the second p-type surface portions 3b are exposed at the n-type drift region 2. The steps 41, 42 are formed concurrently by the first trenches 4 and have the same height. The steps 41, 42 intersect the steps 51, 52 and are continuous in the second direction Y. Between first and second n-type surface portions 2a, 2b, the steps 51 are formed by the second trenches 5 while between first and second p-type surface portions 3b, the steps 52 are formed by the second trenches 5.

The second trenches 5 are each disposed in a stripe-shape intersecting the p⁺-type regions 3; the second trenches 5 intersect the SBDs of the Schottky junction regions 21 and the pn junction diodes of the pn junction regions 22. The second trenches 5 may be orthogonal to the p⁺-type regions 3 (i.e., extend in the first direction X) (refer to FIG. 1) or may intersect the p⁺-type regions 3 at an oblique angle (refer to FIG. 7). The second trenches 5 may intersect the p⁺-type regions 3 so that portions of the n-type drift region 2 most prominent at the front side of the semiconductor substrate 10 (i.e., the first n-type surface portions 2a) are remain; the second trenches 5 may intersect the p⁺-type regions 3 in two or more directions different from each other. In this instance, the second trenches 5 intersecting the p⁺-type regions 3 in different directions from each other are formed at different depths from each other, whereby at locations where the second trenches 5 intersect with the n-type drift region 2 and the p⁺-type regions 3, a difference in heights of the later-described steps 51, 52 may be increased. In FIG. 7, portions of the second trenches 5 (5a, 5b) intersecting the p⁺-type regions 3 at oblique angles and extending in two directions XY1, XY2 different from each other are depicted by bold lines.

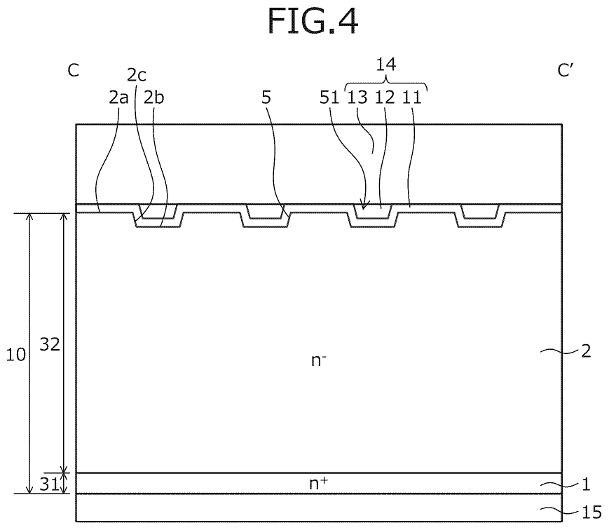

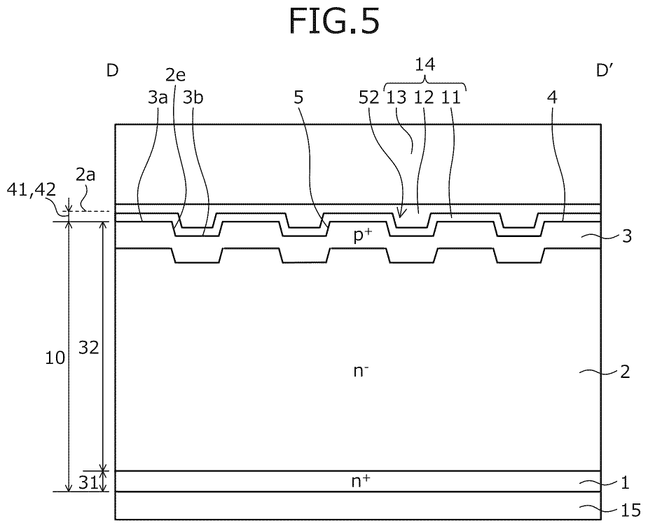

The steps (second steps) 51 where the second n-type surface portions 2b are closer to the n⁺-type cathode region 1 than are the first n-type surface portions 2a are formed at the front surface of the semiconductor substrate 10 by the second trenches 5 (FIG. 4). The first n-type surface portions 2a and the second n-type surface portions 2b are disposed repeatedly alternating with one another in the second direction Y (longitudinal direction of the n-type drift region 2 at the front surface of the semiconductor substrate 10) with the steps 51 intervening therebetween. At third n-type surface portions 2c (the sidewalls of the second trenches 5) connecting the first n-type surface portions 2a and the second n-type surface portions 2b, the n⁻-type drift region 2 is exposed. Further, the steps (third steps) 52 where the second p-type surface portions 3b are closer to the n⁺-type cathode region 1 than are the first p-type surface portions 3a are formed at the front surface of the semiconductor substrate 10 by the second trenches 5 (FIGS. 5 and 6). The first p-type surface portions 3a and the second p-type surface portions 3b are disposed repeatedly alternating with one another in the second direction Y (longitudinal direction of the p⁺-type regions 3) with the steps 52 intervening therebetween. At third p-type surface portions 3c (the sidewalls of the second trenches 5) connecting the first p-type surface portions 3a and the second p-type surface portions 3b, the p⁺-type regions 3 are exposed. The steps 51, 52 are formed concurrently by the second trenches 5 and have the same height. The steps 51, 52 intersect the steps 41, 42 and are continuous in the longitudinal direction of the second trenches 5 (in FIGS. 1 to 6, the first direction X).

At the front side of the semiconductor substrate 10, the first and second trenches 4, 5 and the first n-type surface portions 2a free of any components are highest, at a highest height position (most prominent). The second p-type surface portions 3b (the bottoms of the first and second trenches 4, 5) at intersecting portions of the first trenches 4 and the second trenches 5 are relatively lower by an amount equivalent to a sum of one of the first and one of the second trenches 4, 5 formed at different timings, whereby the second p-type surface portions 3b are at a lowest height position (most recessed toward the n⁺-type cathode region 1). A height position (height differences of the steps 41, 51) of the second n-type surface portions 2b corresponding to the bottoms of the second trenches 5 and a height position of the first p-type surface portions 3a corresponding to the bottoms of the first trenches 4 may be the same. The n-type drift region 2 is exposed at the inner walls of the second trenches 5, at portions where the Schottky junction regions 21 and the second trenches 5 intersect. The p⁺-type regions 3 are exposed at the inner walls of the second trenches 5, at portions where the pn junction regions 22 and the second trenches 5 intersect.

Preferably, a width of each of the bottoms of the second trenches 5 in a lateral direction may be as small as possible and, for example, is smaller than a pitch of the p⁺-type regions 3. Preferably, the width of each of the bottoms of the second trenches 5 in the lateral direction may be a minimum width of etching processing limits. The smaller is the width of each of the bottoms of the second trenches 5 in lateral direction, the greater the number of the second trenches 5 that can be disposed in the active region may be increased. As a result, the exposed surface of the n⁻-type drift region 2 at the front side of the semiconductor substrate 10 may be increased and thus, the area of the Schottky junction increases. The exposed surface of the p⁺-type regions 3 at the front side of the semiconductor substrate 10 increases and thus, the area of contact between the Schottky electrode 11 and the p⁺-type regions 3 also increases. The bottoms of the second trenches 5 may be at positions closer to the n⁺-type cathode region 1 than are the bottoms of the first trenches 4. The greater is the depth of each of the second trenches 5, the more the surfaces of the n⁻-type drift region 2 and the p⁺-type regions 3 may be exposed at the front side of the semiconductor substrate 10.

The second trench 5 is intentionally formed at any timing after the start of the manufacturing processes of the semiconductor device 20 but before the formation of the Schottky electrode 11. For example, the second trenches 5 may be formed concurrently with an alignment mark (a recess constituting the alignment mark for positioning a mask when parts of the device structure are formed). The second trenches 5 are formed concurrently with the alignment mark, whereby manufacturing steps may be omitted and thus, increases in the number of steps in the manufacturing process may be suppressed. In an instance in which the second trenches 5 are formed concurrently with the alignment mark, for example, the second trenches 5 are formed at a pitch of about 0.5 μm to a depth of about 0.4 μm (or a depth of about 0.8 μm). The depth of the alignment mark may be set according to the depth of the second trenches 5.

In an instance in which the second trenches 5 are formed before the p⁺-type regions 3 (the first trenches 4) are formed, a p-type impurity is ion-implanted at the bottoms of the first and second trenches 4, 5 in a later-described ion implantation 65 (refer to FIG. 13) for forming the p⁺-type regions 3. Thus, portions of the p⁺-type regions 3 facing the second trenches 5 in the depth direction Z protrude deeper toward the n⁺-type cathode region 1 than other portions of the p⁺-type regions 3 (FIG. 5). On the other hand, in an instance in which the second trenches 5 are formed after the p⁺-type regions 3 are formed, after the p⁺-type regions 3 are formed by the ion implantation 65 of a p-type impurity to the bottoms of the first trenches, the second trenches 5 are formed to a depth so as to not penetrate through the p⁺-type regions 3. Thus, the depth of the p⁺-type regions 3 from the front surface of the semiconductor substrate 10 is substantially uniform and thus, a lower surface of each of the p⁺-type regions 3 is a substantially flat surface parallel to the front surface of the semiconductor substrate 10 (FIG. 6).

The anode electrode 14 is formed by the Schottky electrode 11, an embedded electrode (second metal layer) 12, and a surface electrode 13 sequentially stacked on the front surface of the semiconductor substrate 10, in the active region. The Schottky electrode 11 is formed along recesses and protrusions resulting from the steps 41, 42, 51, 52 formed by the first and second trenches 4, 5 at a front surface of a semiconductor wafer 60. The Schottky electrode 11 forms a Schottky junction with the n⁻-type drift region 2 at the first to fifth n-type surface portions 2a to 2e and is in contact with the p⁺-type regions 3 at the first to third p-type surface portions 3a to 3c. A material of the Schottky electrode 11 is a metal for which a Schottky barrier height for the n⁻-type drift region 2 is large and a Schottky barrier height for the p⁺-type regions 3 is small and, for example, titanium (Ti) or molybdenum (Mo) may be used.

The embedded electrode 12 is provided on the Schottky electrode 11 so as to be embedded in the first and second trenches 4, 5. The embedded electrode 12 has a function of suppressing an occurrence of unevenness (recesses and protrusions) at the surface of the anode electrode 14 due to the first and second trenches 4, 5 and thereby flattening the surface of the anode electrode 14. As a material of the embedded electrode 12, for example, titanium nitride (TiN) or tungsten (W) may be used. The surface of the anode electrode 14 is flattened, whereby decreases in adhesiveness between the anode electrode 14 and a bonding wire may be suppressed. In an instance in which flattening the surface of the anode electrode 14 is unnecessary, the embedded electrode 12 may be omitted. The surface electrode 13 is, for example, an aluminum (Al) film or an aluminum alloy film containing silicon (Si) or copper (Cu). In an entire area of the back surface of the semiconductor substrate 10, the cathode electrode 15 is provided common to the SBDs of the Schottky junction regions 21 and the pn junction diodes of the pn junction regions 22. The cathode electrode 15 is in ohmic contact with the n⁺-type cathode region 1.

Operation of the semiconductor device 20 according to the first embodiment (SiC-SBD with a JBS structure) is described. In an instance in which forward current flowing in the semiconductor device 20 according to the first embodiment is not more than a rated current value, the forward current flows along a path (current path of the SBDs of the Schottky junction regions 21) in a direction from the anode electrode 14, through the Schottky junction between the Schottky electrode 11 and the n-type drift region 2, to the cathode electrode 15. In an instance in which forward current flowing through the semiconductor device 20 is not more than the rated current value, forward current does not flow in the pn junction diodes of the pn junction regions 22.

At the front surface of the semiconductor substrate 10, the steps 41, 42, 51, 52 are formed by the first and second trenches 4, 5, whereby as compared to an instance in which the front surface of the semiconductor substrate 10 is free of recesses and protrusions of steps formed by trenches (not depicted) or an instance like the reference example (the semiconductor device 120, refer to FIGS. 22 and 23) in which only the first trenches (the trenches 104) are provided, the exposed surface of the n-type drift region 2 at the front side of the semiconductor substrate 10 increases, whereby the area of the Schottky junction increases. Thus, internal resistance of the SBDs of the Schottky junction regions 21 decreases and conduction loss of the SBD is reduced.

When forward current flowing through the semiconductor device 20 during load short-circuit or during on/off of a power source of a circuit in which the semiconductor device 20 is mounted becomes a large current (a surge current or an inrush current) exceeding the rated current value, a path through Schottky junctions between the Schottky electrode 11 and the n-type drift region 2 alone cannot bear the total current and current also flows into the p⁺-type regions 3 from the anode electrode 14 while forward current also flows to the pn junction diodes of the pn junction regions 22. As a result, destruction of the semiconductor device 20 due to a large current may be suppressed. On the other hand, during reverse bias with respect to the anode electrode 14 when positive voltage (reverse voltage) is applied to the cathode electrode 15, a depletion layer spreads in the p⁺-type regions 3 and the n-type drift region 2 from the pn junctions between the p⁺-type regions 3 and the n⁻-type drift region 2. When the reverse voltage becomes high, depletion layers between the p⁺-type regions 3, which are adjacent to one another, are connected and punch-through. As a result, a location where electric field is maximal moves from the front surface of the semiconductor substrate 10 to the lower surfaces of the p⁺-type regions 3, thereby reducing the electric field applied to the front surface of the semiconductor substrate 10 and thus, suppressing leakage current.

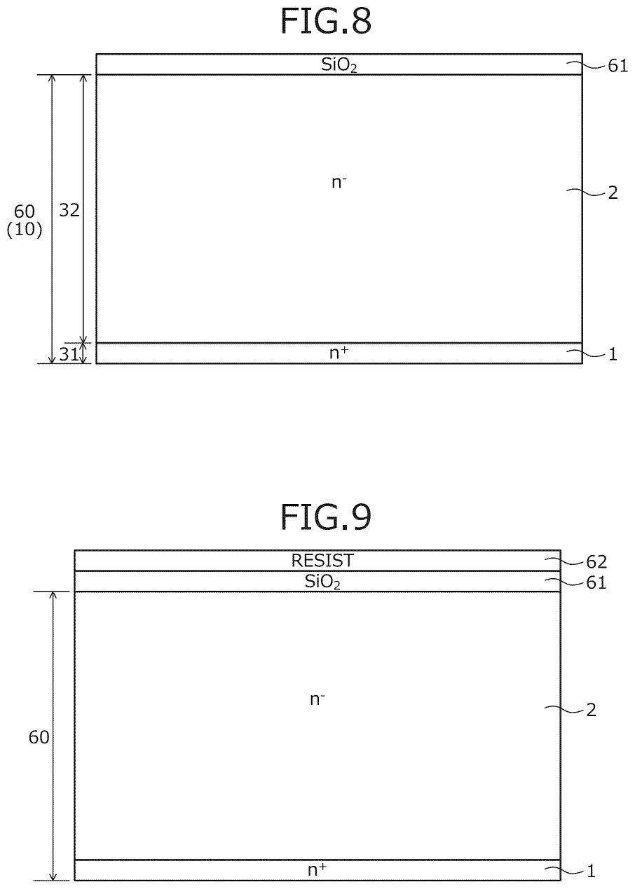

A method of manufacturing the semiconductor device 20 according to the first embodiment is described. FIGS. 8, 9, 10, 11, 12, 13, 14, and 15 are cross-sectional views depicting states of the semiconductor device according to the first embodiment during manufacture. FIGS. 8 to 15 depict cross-sections corresponding to FIG. 3. First, as depicted in FIG. 8, on a front surface of a starting wafer (a portion thereof constituting the n⁺-type starting substrate 31 after dicing) containing SiC, the n⁻-type epitaxial layer 32 constituting the n-type drift region 2 is grown by epitaxy, whereby the semiconductor wafer 60 containing SiC is fabricated. The semiconductor wafer 60 has, as the front surface, a first main surface having the n⁻-type epitaxial layer 32 and, as the back surface, a second main surface having the starting wafer.

Next, by photolithography and etching, the alignment mark (not depicted) is formed in a non-operating region of the semiconductor wafer 60, at the front surface of the semiconductor wafer 60; and the second trenches 5 (refer to FIG. 1) are formed in an operating region of the semiconductor wafer 60, at the front surface of the semiconductor wafer 60. An operating region of the semiconductor wafer 60 is a region diced from the semiconductor wafer 60 and included in a semiconductor chip (the semiconductor substrate 10). A non-operating region of the semiconductor wafer 60 is a region of a dicing line or the like and is not included in a semiconductor chip. Next, an oxide film (SiO₂ film) 61 is formed at the front surface of the semiconductor wafer 60.

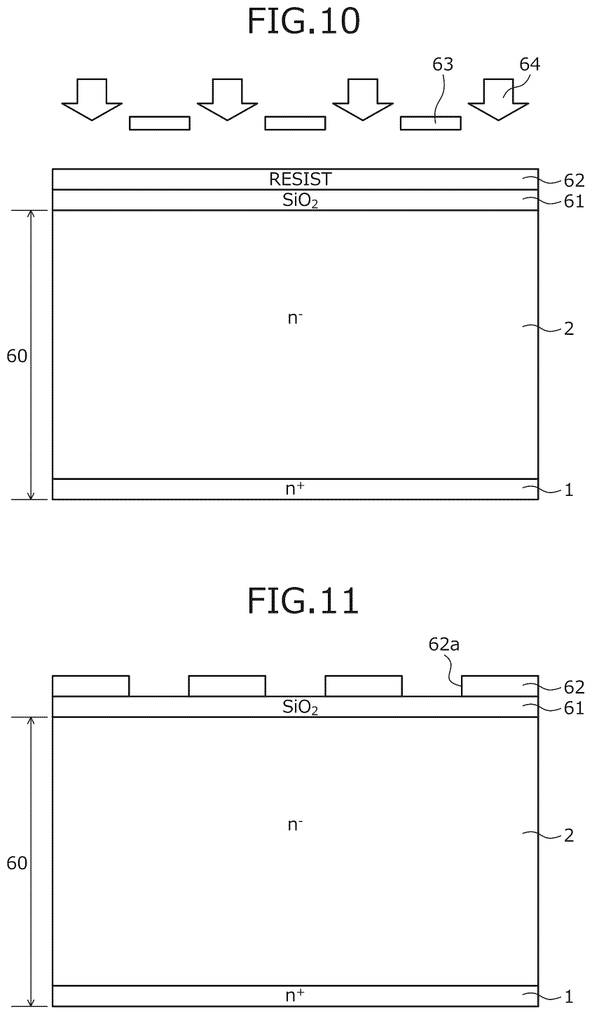

Next, as depicted in FIG. 9, a resist film 62 is formed on the oxide film 61. Next, as depicted in FIG. 10, a mask (reticle) 63 having a pattern of the p⁺-type regions 3 is positioned using the alignment mark (not depicted) as a reference. Next, light 64 of a predetermined light source passes through the mask 63 and is irradiated on the resist film 62, whereby the pattern of the mask 63 is projected and transferred to the resist film 62 (exposure). Next, as depicted in FIG. 11, exposed portions of the resist film 62 melt (are developed), thereby forming, in the resist film 62, openings 62a in a same pattern as the pattern of the mask 63.

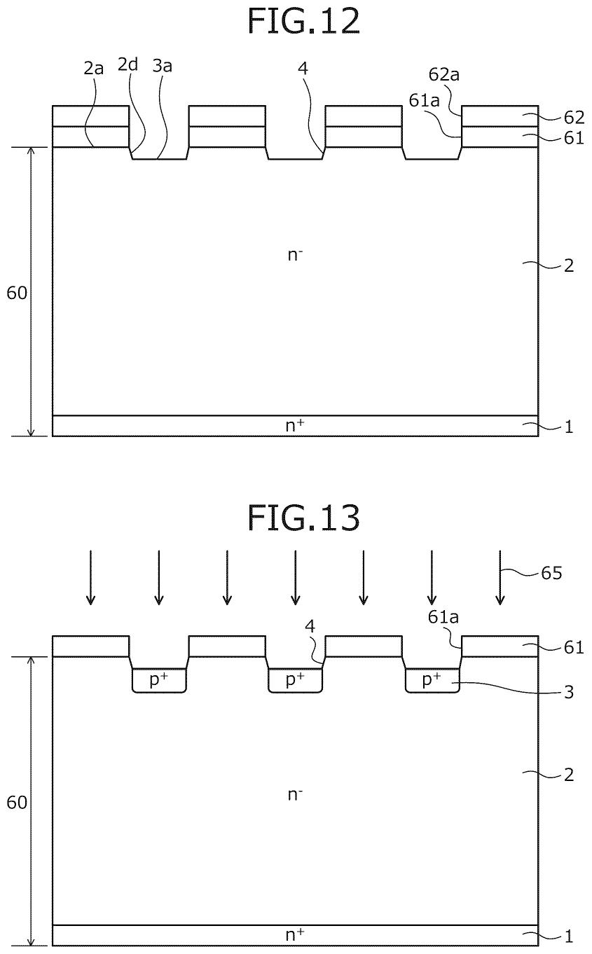

Next, as depicted in FIG. 12, the oxide film 61 is partially removed by etching using the resist film 62 as a mask, thereby forming, in the oxide film 61, openings 61a that expose portions corresponding to formation regions of the p⁺-type regions 3. The etching of the oxide film 61 is assumed to be over-etching so that the openings 61a penetrate through the oxide film 61 with certainty in the depth direction Z. By this over-etching, at the portions exposed by the openings 61a of the oxide film 61, surface regions (SiC portions) of the semiconductor wafer 60 are removed at the front surface of the semiconductor wafer 60, thereby forming the first trenches 4 in the semiconductor wafer 60, at the front surface of the semiconductor wafer 60.

During the over-etching, etching of the SiC portions also advances in a direction (horizontal direction) parallel to the front surface of the semiconductor wafer 60 and thus, a width of each of the first trenches 4, near the openings of the first trenches 4 is slightly wider than the width of each of the openings 61a of the oxide film 61. The first trenches 4 are formed, whereby the steps 41, 42, 51, 52 of differing heights due to the first and second trenches 4, 5 are formed at the front surface of the semiconductor wafer 60 (refer to FIG. 1). A period of the over-etching may be intentionally long to increase the depth of the first trenches 4. Subsequently, the resist film 62 is removed.

Next, as depicted in FIG. 13, the ion implantation 65 of a p-type impurity is performed using remaining portions of the oxide film 61 as a mask, whereby the p⁺-type regions 3 are formed in regions at the surface of the bottoms of the first trenches 4 (the first to third p-type surface portions 3a to 3c). At the sidewalls (the fourth and fifth n-type surface portions 2d, 2e) of the first trenches 4, the ion implantation 65 of a p-type impurity is not performed. Thus, portions (the first to the third n-type surface portions 2a to 2c) exposed by the oxide film 61 and the sidewalls of the first trenches 4 are maintained in the state of the n-type epitaxial layer 32 (the n-type drift region 2) at the time of epitaxial growth.

Even in an instance in which the second trenches 5 are formed after the p⁺-type regions 3 are formed, the n⁻-type drift region 2 is exposed at the first to fifth n-type surface portions 2a to 2e. Due to the first trenches 4, the steps 42 formed by the difference in height (height difference) between the second n-type surface portions 2b (portions of the upper surface of the n-type drift region 2) and the second p-type surface portions 3b (the upper surfaces of the p⁺-type regions 3) move to lower positions closer to the n⁺-type cathode region 1 overall due to the second trenches 5; contact surfaces (surfaces forming an interface) of the n⁻-type drift region 2 where the n⁻-type drift region 2 is in contact with the p⁺-type regions 3 are exposed as the fifth n-type surface portions 2e connecting the second n-type surface portions 2b and the second p-type surface portions 3b.

Even in an instance in which the second trenches 5 are formed after the p⁺-type regions 3 are formed, the p⁺-type regions 3 are exposed at the first to third p-type surface portions 3a to 3c. The steps 52 due to the difference in height (height difference) between the first and second p-type surface portions 3a, 3b due to the second trenches 5, are formed at the upper surfaces (the bottoms of the first trenches 4) of the p⁺-type regions 3. The bottoms of the second trenches 5 (the second p-type surface portions 3b) are at shallower depth positions closer to the front surface of the semiconductor wafer 60 than are the bottom surfaces of the p⁺-type regions 3, whereby the p⁺-type regions 3 are exposed at the sidewalls of the second trenches 5 (the third p-type surface portions 3c) at the upper surfaces of the p⁺-type regions 3.

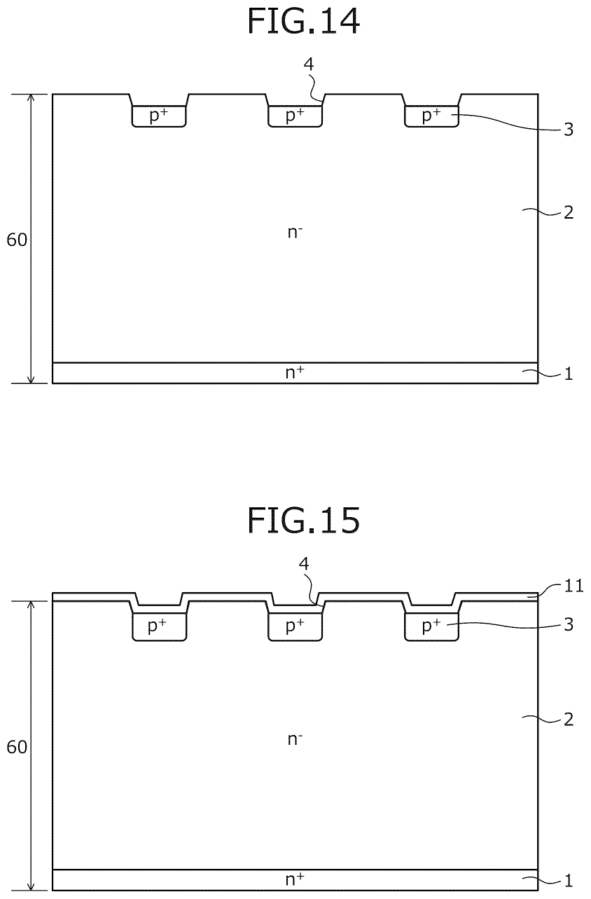

Next, as depicted in FIG. 14, the remaining portions of the oxide film 61 are removed. Subsequently, as depicted in FIG. 15, by a general method, the Schottky electrode 11 is formed at the front surface of the semiconductor wafer 60 by a silicide reaction with the semiconductor wafer 60. The Schottky electrode 11 is a nickel silicide (NixSiy, where, x, y are positive integers) film formed along the front surface of the semiconductor wafer 60 and the inner walls of the first and second trenches 4, 5 by causing, for example, Ni in a nickel (Ni) film and SiC in the semiconductor wafer 60 to react with each other by a heat treatment.

The heat treatment for converting the Schottky electrode 11 into a silicide also serves as a heat treatment for activating the p-type impurity implanted into the semiconductor wafer 60 by the ion implantation 65. A heat treatment (activation annealing) for activating impurities ion-implanted into the semiconductor wafer 60 may be performed at a different timing from the heat treatment for converting the Schottky electrode 11 into a silicide. Impurities in SiC have a small diffusion coefficient and diffuse minimally. Therefore, even after the activation annealing, the depth of the p⁺-type regions 3 is only slightly increased and the sidewalls of the first trenches 4 are maintained as an n-type.

Next, on the Schottky electrode 11, the embedded electrode 12 is formed so as to be embedded in the first and second trenches 4, 5 and the surface electrode 13 is formed on the embedded electrode 12, whereby the anode electrode 14 in which the Schottky electrode 11, the embedded electrode 12, and the surface electrode 13 are sequentially stacked is formed. The cathode electrode 15 is formed at the back surface of the semiconductor wafer 60.

Thereafter, the operating regions of the semiconductor wafer 60 are diced (cut) from the semiconductor wafer 60 as individual semiconductor chips (the semiconductor substrate 10), whereby the SiC-SBD of the JBS structure depicted in FIGS. 1 to 5 is completed.

As described above, according to the first embodiment, in the JBS structure in which both the Schottky junctions and the pn junctions are present, the first trenches that are formed as a secondary consequence of the over-etching during the formation of the ion implantation mask for forming the p⁺-type regions that form the pn junctions of the JBS structure, and the second trenches that are intentionally formed, are each provided in the semiconductor substrate, at the front surface thereof. The SBDs formed by the Schottky junctions and the pn junction diodes formed by the pn junctions are disposed adjacently to one another and extend in a direction parallel to the front surface of the semiconductor substrate. The second trenches are each provided in a stripe-shape intersecting the p⁺-type regions at a depth shallower than the depth of the p⁺-type regions forming the pn junctions of the JBS structure; the second trenches intersect the SBDs and the pn junction diodes. Due to the first and second trenches, three or more steps of differing heights are disposed repeatedly in a predetermined pattern at the front surface of the semiconductor substrate.

By the steps due to the first and second trenches, the exposed surface of the n⁻-type drift region at the front side of the semiconductor substrate increases and thus, the area of contact between (area of the Schottky junction between) the n-type drift region and the Schottky electrode increases. For example, in an instance in which the second trenches are formed having a pitch of 0.5 μm, a depth of 0.4 μm, a bottom width of 0.5 μm, as compared to an instance in which the recesses and protrusions (unevenness) of the steps due to the trenches at the front surface of the semiconductor substrate are absent, the area of the Schottky junction increases by 1.8 times or more. Thus, in an instance in which the internal resistance of the SBDs decreases and the chip size is maintained, conduction loss of the SBD decreases. In an instance in which conduction loss of the SBD is maintained, the chip size may be reduced and the number of semiconductor chips that may be fabricated from a single semiconductor wafer increases and thus, costs may be reduced.

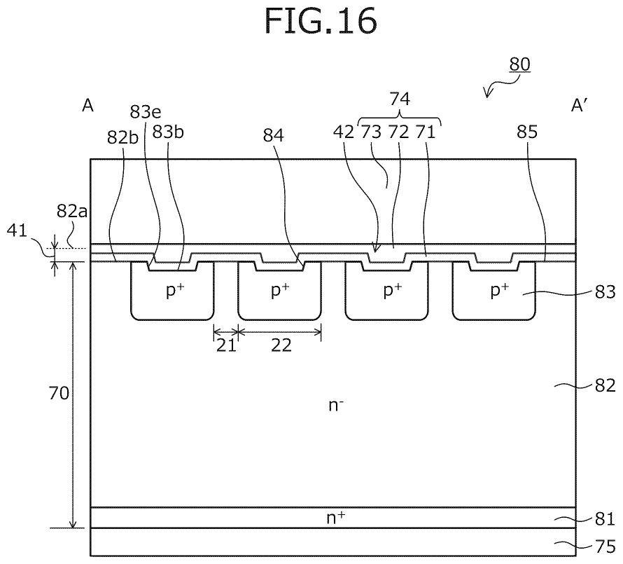

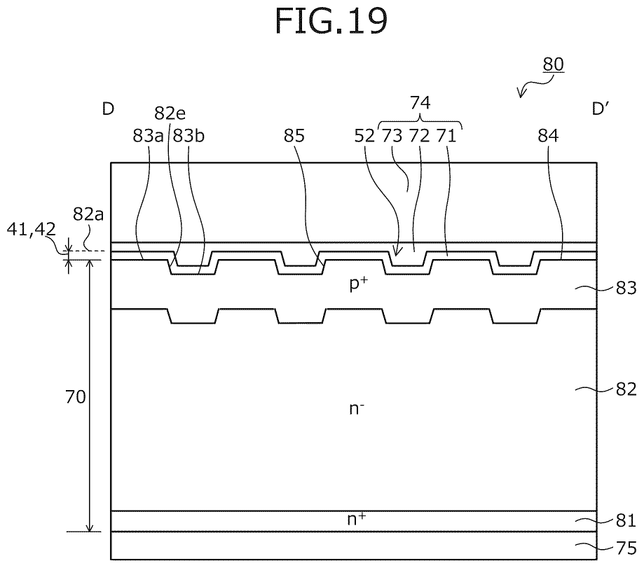

A structure of a semiconductor device according to a second embodiment is described. FIGS. 16, 17, 18, and 19 are cross-sectional views depicting the structure of the semiconductor device according to the second embodiment. Reference characters 81, 82, 82a to 82e, 83, 83a to 83c, 84, 85, 70 to 75 correspond, respectively, to reference characters 1, 2, 2a to 2e, 3, 3a to 3c, 4, 5, 10 to 15 in FIG. 1, and in the structure, a width of each of the p⁺-type regions 83 is wider than a width of each of the first trenches 84, cross-sections of the structure along cutting line A-A′, cutting line B-B′, cutting line C-C′, and cutting line D-D′ correspond to FIGS. 16 to 19, respectively. In FIGS. 16 and 19, a height position of first surface portions 82a of the front surface of the semiconductor substrate 70 is indicated by a dashed line.

A semiconductor device 80 according to the second embodiment is a device in which the semiconductor device 20 according to the first embodiment (refer to FIGS. 1 to 5) is applied to a Si-SBD of a JBS structure having silicon (Si) as a semiconductor material. In the second embodiment, as compared to SiC, the diffusion coefficient of an impurity in Si is large and thus, the width of each of the p⁺-type regions 83 configuring the JBS structure in a front side of the semiconductor substrate (semiconductor chip) 70 is wider than the width of each of the first trenches 84, which are formed as a secondary consequence of the over-etching during the formation of the p⁺-type regions 83.

The semiconductor substrate 70 is an n⁻-type single crystal bulk substrate containing Si. At the front side of the semiconductor substrate 70, the p⁺-type regions 83 configuring the JBS structure, the first and second trenches 84, 85 forming the steps 41, 42, 51, 52 at the front side of the semiconductor substrate 70, a Schottky electrode 71 configuring an anode electrode 74, an embedded electrode 72, and a surface electrode 73 are provided. At a back side of the semiconductor substrate 70, an n⁺-type cathode region 81 and a cathode electrode 75 are provided.

The n⁺-type cathode region 81 is provided between a back surface of the semiconductor substrate 70 and the n-type drift region 82. Configuration of the n⁺-type cathode region 81 is similar to the configuration of the n⁺-type cathode region 1 of the first embodiment, excluding the n⁺-type cathode region 1 being a diffused region formed by ion implantation. Configuration of the anode electrode 74 (the Schottky electrode 71, the embedded electrode 72, and the surface electrode 73) and configuration of the cathode electrode 75 are similar, respectively, to the configuration of the anode electrode 14 (the Schottky electrode 11, the embedded electrode 12, and the surface electrode 13) and the configuration of the cathode electrode 15 of the first embodiment.

A portion of the n-type semiconductor substrate 70 excluding the n⁺-type cathode region 81 and the p⁺-type regions 83 constitutes the n-type drift region 82. The p⁺-type regions 83 are provided between the n-type drift region 82 and inner walls (sidewalls and bottom) of the first trenches 84, the p⁺-type regions 83 being in contact with the n-type drift region 82 and underlying the inner walls of the first trenches 84. The p⁺-type regions 83 are exposed at the entire surface of the inner walls of the first trenches 84. The configuration of the p⁺-type regions 83 is a same configuration as the configuration of the p⁺-type regions 3 of the first embodiment, excluding the p⁺-type regions 83 being exposed at the entire surface of the inner walls of the first trenches 84.

The first and second trenches 84, 85, respectively, are formed similarly to the first and second trenches 4, 5 of the first embodiment. The configurations of the steps 41, 42, 51, 52 at the front surface of the semiconductor substrate 70 and formed by the first and second trenches 84, 85 are, respectively, the same as the configurations of the steps 41, 42, 51, 52 at the front surface of the semiconductor substrate 10 of the first embodiment. In the second embodiment, at the front side of the semiconductor substrate 70, the surfaces of the p⁺-type regions 83 exposed by the steps 41, 42, 51, 52 increase, and the area of contact between the Schottky electrode 71 and the p⁺-type regions 83 increases.

In particular, the first trenches 84 are formed in a same pattern as the pattern of the mask openings due to the over-etching during the formation of the ion implantation mask used to form the p⁺-type regions 83 and thereby, are formed in the same pattern as the pattern of the p⁺-type regions 83 during ion implantation. Due to the diffusion of the impurity by the subsequent activation annealing treatment, the width of each of the p⁺-type regions 83 increases and along the inner walls of the first trenches 84, reaches the later-described first to third surface portions 82a, 82b, 82c (in an instance in which the second trenches 85 are formed after the p⁺-type regions 83 are formed, the front surface of the semiconductor substrate 70). Thus, the p⁺-type regions 83 underlie the entire surface of the inner walls of the first trenches 84. The n⁻-type drift region 82 is not exposed at the inner walls of the first trenches 84.

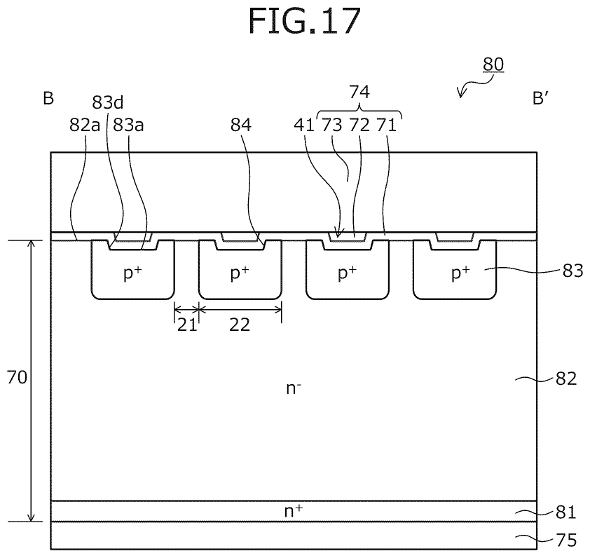

Due to the first trenches 84, the steps 41, 42 that lower the upper surfaces (first and second p-type surface portions) 83a, 83b of the p⁺-type regions 83 to be closer to the n⁺-type cathode region 81 than are portions (hereinafter, the first and second surface portions) 82a, 82b of the upper surface of the n-type drift region 82 are formed in plural at the front surface of the semiconductor substrate 70 (FIGS. 17 and 16). The p⁺-type regions 83 extend to the first and second surface portions 82a, 82b via the steps 41, 42. The steps 51 are formed intervening between the first and second surface portions 82a, 82b adjacent to one another in the second direction Y longitudinal direction of the n⁻-type drift region 82 at (the front surface of the semiconductor substrate 70). The steps 52 are formed intervening between the first and second p-type surface portions 83a, 83b adjacent to one another in the second direction Y (longitudinal direction of the p⁺-type regions 83).

The first surface portions 82a and the first p-type surface portions 83a are disposed repeatedly alternating with one another in the longitudinal direction of the second trenches 85 with the steps 41 intervening therebetween. At fourth p-type surface portions 83d (the sidewalls of the first trenches 4) connecting the first surface portions 82a and the first p-type surface portions 83a, the p⁺-type regions 83 are exposed. The second surface portions 82b and the second p-type surface portions 83b are disposed repeatedly alternating with one another in the longitudinal direction of the second trenches 85 with the steps 42 intervening therebetween. At fifth p-type surface portions 83e (the sidewalls of the first trenches 4) connecting the second surface portions 82b and the second p-type surface portions 83b, the p⁺-type regions 83 are exposed. The steps 41, 42 are formed concurrently by the first trenches 84 and have the same height. The steps 41, 42 are continuous in the second direction Y.

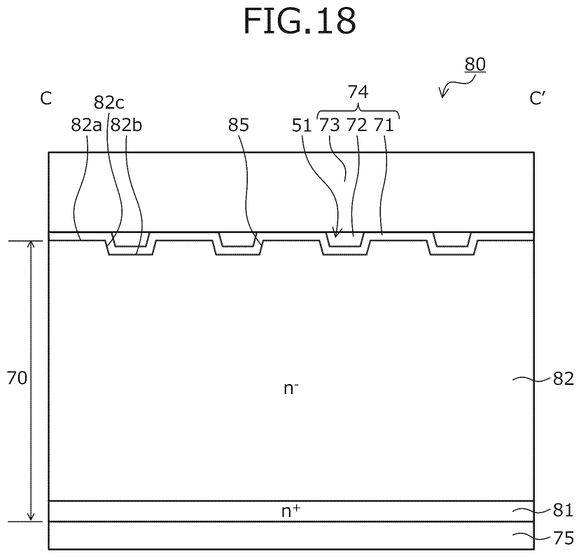

The second trenches 85, similar to the second trenches 5 of the first embodiment, are each provided in a stripe-shape intersecting the p⁺-type regions 83 configuring the JBS structure. Due to the second trenches 85, at the front surface of the semiconductor substrate 70, the steps 51 that lower the second surface portions 82b closer to the n⁺-type cathode region 81 than are the first surface portions 82a are formed (FIG. 18). The first surface portions 82a and the second surface portions 82b are disposed repeatedly alternating with one another in the second direction Y with the steps 51 intervening therebetween. At the third surface portions 82c (the sidewalls of the second trenches 85) connecting the second surface portions 82b with the first and second surface portions 82a, 82b and the first surface portions 82a, the n⁻-type drift region 82 are exposed and the p⁺-type regions 83 are exposed.

Further, due to the second trenches 85, the steps 52 that lower the second p-type surface portions 83b closer to the n⁺-type cathode region 81 than are the first p-type surface portions 83a are formed at the front surface of the semiconductor substrate 70 (FIG. 19). The first p-type surface portions 83a and the second p-type surface portions 83b are disposed repeatedly alternating with one another in the second direction Y with the steps 52 intervening therebetween. At the third p-type surface portions 83c (the sidewalls of the second trenches 5) connecting the first p-type surface portions 83a and the second p-type surface portions 83b, the p⁺-type regions 83 are exposed. The steps 51, 52 are formed concurrently and have the same height. The steps 51, 52 are intersected by the steps 41, 42 and are continuous in the longitudinal direction of the second trenches 85 (in FIGS. 16 to 19, the first direction X).

As described, due to the first and second trenches 84, 85, the exposed surfaces of the p⁺-type regions 83 at the front side of the semiconductor substrate 70 increases. At the front side of the semiconductor substrate 70, the first and second trenches 84, 85 and the first surface portions 82a free of any components are at the highest height position. The second p-type surface portions 83b at intersecting portions of the first trenches 84 and the second trenches 85 are lower by an amount equivalent to a sum of one of the first and one of the second trenches 84, 85 formed at different timings, whereby the second p-type surface portions 83b are at the lowest height position. The height position of the second surface portions 82b corresponding to the second trenches 85 and the height position of the first p-type surface portions 83a corresponding to the first trenches 84 may be the same.

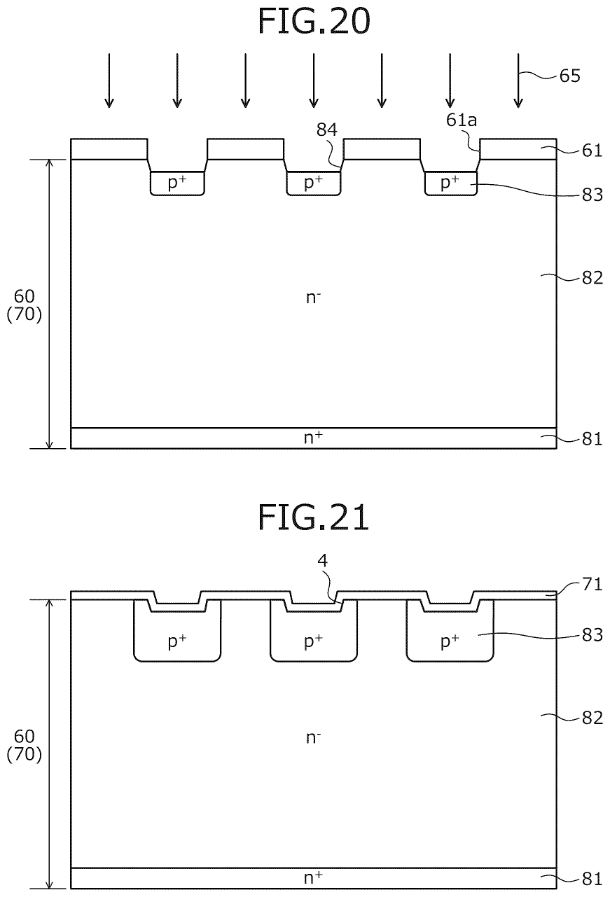

A method of manufacturing the semiconductor device 80 according to the second embodiment is similar to the method of manufacturing the semiconductor device 20 according to the first embodiment, excluding use of the n⁻-type single crystal bulk substrate containing Si as the semiconductor wafer 60 constituting the semiconductor substrate 70 and a greater diffusion of the impurity by the activation annealing treatment (refer to FIGS. 8 to 12). FIGS. 20 and 21 are cross-sectional views depicting states of the semiconductor device according to the second embodiment during manufacture. FIGS. 20 and 21 depict cross-sections corresponding to FIG. 17.

First, similar to the first embodiment, by photolithography and etching, the alignment mark (not depicted) and the second trenches 85 (refer to FIGS. 18 and 19) are formed at the front surface of the semiconductor wafer 60 containing Si. The semiconductor wafer 60 may be a semiconductor wafer in which the n-type epitaxial layer (the n-type drift region 82) is grown by epitaxy on a front surface of an n⁺-type single crystal bulk wafer (the n⁺-type cathode region 81) containing Si.

Next, as depicted in FIG. 20, similar to the first embodiment, the oxide film 61 opened at portions corresponding to formation regions of the p⁺-type regions 83 is formed on the front surface of the semiconductor wafer 60 by photolithography and etching. The steps 41, 42, 51, 52 having different height positions due to the first and second trenches 84, 85 are formed at the front surface of the semiconductor wafer 60 by the over-etching during the formation of the oxide film 61.

Next, similar to the first embodiment, the ion implantation 65 of a p-type impurity is performed using remaining portions of the oxide film 61 as a mask, whereby the p⁺-type regions 83 are formed in regions at the surface of the bottoms of the first trenches 84 (the first to third p-type surface portions 83a to 83c). Next, as depicted in FIG. 21, the remaining portions of the oxide film 61 are removed and thereafter, similar to the first embodiment, the Schottky electrode 71 is formed at the front surface of the semiconductor wafer 60 by a silicide reaction with the semiconductor wafer 60.

Here, similar to the first embodiment, the heat treatment for converting the Schottky electrode 71 into a silicide also serves as the heat treatment for activating the p-type impurity implanted into the semiconductor wafer 60 by the ion implantation 65. As compared to SiC, impurities in Si diffuse easily, whereby impurities diffuse radially in the semiconductor wafer 60 from the bottoms of the first trenches 84 due to the heat treatment and thus, the p⁺-type regions 83 underlie the entire surface (the fourth and fifth p-type surface portions 83d, 83e) of the inner walls of the first trenches 4.

Next, similar to the first embodiment, the embedded electrode 72 and the surface electrode 73 are formed on the Schottky electrode 71, whereby the anode electrode 74 is formed. At the back side of the semiconductor wafer 60, the n⁺-type cathode region 81 and the cathode electrode 75 are formed. Thereafter, the operating regions of the semiconductor wafer 60 are diced from the semiconductor wafer 60 into individual semiconductor chips (the semiconductor substrate 70), whereby SiC-SBD of the JBS structure depicted in FIGS. 16 to 19 is completed.

As described above, according to the second embodiment, the first embodiment is applied to an SBD of a JBS structure having Si as a semiconductor material, whereby the surface of the p⁺-type regions exposed at the front side of the semiconductor substrate increases and thus, the area of contact between the p⁺-type regions and the Schottky electrode at the front side of the semiconductor substrate increases. Accordingly, in an instance in which the chip size is maintained, the allowable amount of current of the pn junction diode increases and the amount of tolerance against large current exceeding the rated current is enhanced. In an instance in which the allowable amount of current of the pn junction diode is maintained, the chip size may be reduced and the number of semiconductor chips that may be fabricated from a single semiconductor wafer increases and thus, costs may be reduced. Further, according to the second embodiment, the p⁺-type regions forming the pn junctions of the JBS structure underlie the entire surface of the inner walls of the first trenches, whereby the area of the pn junctions increases and thus, the effect of suppressing leakage current during reverse bias increases.

In the foregoing, the present invention is not limited to the embodiments described herein and may be variously modified within a range not departing from the spirit of the present invention.

According to the invention described above, the surface of first-conductivity-type region or the surfaces of the second-conductivity-type regions exposed at a first main side of the semiconductor substrate increases and thus, the area of contact between the Schottky electrode and, the first-conductivity-type region or the second-conductivity-type regions at the first mains side of the semiconductor substrate increases. When the area of contact between the first-conductivity-type region and the Schottky electrode increases, the internal resistance of the SBD decreases, whereby the conduction loss of the SBD decreases. When the area of contact between the second-conductivity-type regions and the Schottky electrode increases, the amount of allowable current of the pn junction diodes formed by the pn junctions between the second-conductivity-type regions and the first-conductivity-type region increases, thereby enhancing the tolerance against large currents exceeding the rated current.

The semiconductor device according to the present invention achieves an effect in that a semiconductor device having a JBS structure with improved electrical characteristics may be provided.

As described above, the semiconductor device according to the present invention is useful for power semiconductor devices used in power converting equipment, power source devices of various types of industrial machines, etc. and is particularly suitable in instances in which the semiconductor material is SiC.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, having a first main surface and a second main surface opposite to each other, the semiconductor substrate having a first-conductivity-type region at the first main surface thereof;
a second-conductivity-type region of a second conductivity type, selectively provided at the first main surface of the semiconductor substrate, both the second-conductivity-type region, and the first-conductivity-type region extending along the second-conductivity-type region, extend at the first main surface in a first direction parallel to the first main surface;
a first electrode provided at the first main surface of the semiconductor substrate, the first electrode forming a Schottky junction with the first-conductivity-type region and being in contact with the second-conductivity-type region at the first main surface; and
a second electrode provided at the second main surface of the semiconductor substrate, wherein
an upper surface of the first-conductivity-type region includes a plurality of first-conductivity-type upper surface portions, and an upper surface of the second-conductivity-type region includes a plurality of second-conductivity-type upper surface portions, the plurality of first-conductivity-type upper surface portions and the plurality of second-conductivity-type upper surface portions being aligned in both the first direction and a second direction, which is parallel to the first main surface and perpendicular to the first direction;
in the second direction, each of the first-conductivity-type upper surface portions has a first difference in height, in a depth direction of the semiconductor device, with one of the second-conductivity-type upper surface portions adjacent thereto, to thereby form a first step therebetween;
in the first direction, each of the first-conductivity-type upper surface portions has a second difference in height, in the depth direction of the semiconductor device, with one of the first-conductivity-type upper surface portions adjacent thereto, to thereby form a second step therebetween; and
in the first direction, each of the second-conductivity-type upper surface portions has a third difference in height, in the depth direction of the semiconductor device, with one of the second-conductivity-type upper surface portions adjacent thereto, to thereby form a third step therebetween.

2. The semiconductor device according to claim 1, further comprising:
a first trench provided at the first main surface of the semiconductor substrate, and extending along the second-conductivity-type region in the first direction, a bottom of the first trench being in the second-conductivity-type region; and
a second trench provided at the first main surface and intersecting the first-conductivity-type region and the second-conductivity-type region, a bottom of the second trench having portions thereof in the first-conductivity-type region and the second-conductivity-type region, respectively, wherein
the plurality of first steps is formed at the first trench, and
the plurality of second steps and the plurality of third steps are formed at the second trench.

3. The semiconductor device according to claim 2, wherein the second-conductivity-type region, at a portion thereof facing the second trench at least in the depth direction of the semiconductor device, is closer to the second main surface of the semiconductor substrate than is the bottom of the second trench.

4. The semiconductor device according to claim 3, wherein a depth of the second-conductivity-type region from the first main surface of the semiconductor substrate is uniform across the entire second-conductivity-type region.

5. The semiconductor device according to claim 2, wherein in the depth direction of the semiconductor device, the bottom of the second trench is closer to the second main surface of the semiconductor substrate than is the bottom of the first trench.

6. The semiconductor device according to claim 2, wherein
the second-conductivity-type region extends in a first striped shape in the first direction,
the second trench extends in a second striped shape and intersects the first-conductivity-type region and the second-conductivity-type region, and
a width of the second trench is narrower than an interval of the first striped shape.

7. The semiconductor device according to claim 2, wherein the first trench is formed fully in the second-conductivity-type region.

8. The semiconductor device according to claim 2, wherein the first electrode has:
a first metal layer provided on the first main surface, an inner wall of the first trench, and an inner wall of the second trench, the first metal layer forming the Schottky junction with the first-conductivity-type region and being in contact with the second-conductivity-type region, and
a second metal layer provided on the first metal layer in the first trench and in the second trench, the second metal layer being embedded in the first trench and the second trench.

9. The semiconductor device according to claim 8, wherein the second metal layer contains titanium nitride or tungsten.

10. A semiconductor device, comprising:
a semiconductor substrate of a first conductivity type, having a first main surface and a second main surface opposite to each other, the semiconductor substrate including a first-conductivity-type region at the first main surface thereof;
a first trench provided at the first main surface of the semiconductor substrate and extending in a first direction parallel to the first main surface;
a second-conductivity-type region selectively provided in the semiconductor substrate, the second-conductivity-type region extending along the first trench in the first direction, underlying a bottom of the first trench, and extending along the first-conductivity-type region in the first direction;
a second trench provided at the first main surface and intersecting the first-conductivity-type region and the second-conductivity-type region, a bottom of the second trench having portions thereof in the first-conductivity-type region and the second-conductivity-type region, respectively;
a first electrode provided at the first main surface and being embedded in the first trench and the second trench, the first electrode forming a Schottky junction with the first-conductivity-type region and being in contact with second-conductivity-type region;
a second electrode provided at the second main surface of the semiconductor substrate.

11. The semiconductor device according to claim 10, wherein the second-conductivity-type region, at a portion thereof facing the second trench at least in a depth direction of the semiconductor device, is closer to the second main surface of the semiconductor substrate than is the bottom of the second trench.

12. The semiconductor device according to claim 11, wherein a depth of the second-conductivity-type region from the first main surface of the semiconductor substrate is uniform across the entire second-conductivity-type region.

13. The semiconductor device according to claim 10, wherein in the depth direction of the semiconductor device, the bottom of the second trench is closer to the second main surface of the semiconductor substrate than is the bottom of the first trench.

14. The semiconductor device according to claim 10, wherein
the second-conductivity-type region extends in a first striped shape in the first direction,
the second trench extends in a second striped shape in a second direction and intersects the first-conductivity-type region and the second-conductivity-type region, the second direction being parallel to the first main surface and perpendicular to the first direction, and
a width of the second trench is narrower than an interval of the first striped shape.

15. The semiconductor device according to claim 10, wherein the first trench is formed fully in the second-conductivity-type region.

16. The semiconductor device according to claim 10, wherein the first electrode has:
a first metal layer provided on the first main surface, an inner wall of the first trench, and an inner wall of the second trench, the first metal layer forming the Schottky junction with the first-conductivity-type region and being in contact with the second-conductivity-type region, and
a second metal layer provided on the first metal layer in the first trench and in the second trench, the second metal layer being embedded in the first trench and the second trench.

17. The semiconductor device according to claim 16, wherein the second metal layer contains titanium nitride or tungsten.
